(19) United States
(12) Patent Application Publication
(10) Pub. No.: US 2025/0162040 A1
(43) Pub. Date: May 22, 2025

(54) COATED TOOL AND CUTTING TOOL

(71) Applicant: KYOCERA CORPORATION, Kyoto-shi, Kyoto (JP)

(72) Inventor: Ryoma NOMIYAMA, Satsumasendai-shi, Kagoshima (JP)

(21) Appl. No.: 18/841,675

(22) PCT Filed: Feb. 7, 2023
(86) PCT No.: PCT/JP2023/004059

§ 371 Date: Aug. 27, 2024

(30) Foreign Application Priority Data
Feb. 28, 2022 (JP) 2022-030391

(51) Int. Cl. B23B 27/14

(52) U.S. Cl. CPC B23B 27/148; B23B 2228/105

(57) ABSTRACT

A coated tool according to the present disclosure includes a base body and a coating layer located on a surface of the base body. The coating layer contains at least one element selected from Group 4a, 5a and 6a elements under the periodic table, Al, Si, B, Y, and Mn, and at least one element selected from C and N. In the coated tool according to the present disclosure, a difference between a maximum value and a minimum value of a reflectance of the coating layer in a wavelength range of 400 nm or more and 1500 nm or less is 15% or less of the maximum value.

### CROSS-REFERENCE TO RELATED APPLICATIONS

This application is national stage application of International Application No. PCT/JP2023/004059, filed on Feb. 7, 2023, which designates the United States, and which claims the benefit of priority from Japanese Patent Application No. 2022-030391, filed on Feb. 28, 2022.

### TECHNICAL FIELD

The present disclosure relates to a coated tool and a cutting tool.

### BACKGROUND OF INVENTION

As a tool used for cutting processing such as turning processing or milling processing, a coated tool is known in which a surface of a base body made of cemented carbide alloy, cermet, ceramic, or the like is coated with a coating layer to improve wear resistance, and the like.

### CITATION LIST

### Patent Literature

Patent Document 1: WO 2019/146710
Patent Document 2: WO2011/016488
Patent Document 3: WO2010/007958

### SUMMARY

A coated tool according to an aspect of the present disclosure includes a base body and a coating layer located on a surface of the base body. The coating layer contains at least one element selected from Group 4a, 5a and 6a elements under the periodic law, Al, Si, B, Y, and Mn, and at least one element selected from C and N. In the coated tool according to the present disclosure, a difference between a maximum value and a minimum value of a reflectance of the coating layer in a wavelength range of 400 nm or more and 1500 nm or less is 15% or less of the maximum value.

### BRIEF DESCRIPTION OF THE DRAWINGS

FIG. 1 is a perspective view illustrating an example of a coated tool according to an embodiment.

FIG. 2 is a side sectional view illustrating an example of the coated tool according to the embodiment.

FIG. 3 is a schematic enlarged view of a corner portion in a tip body according to a reference example.

FIG. 4 is a cross-sectional view illustrating an example of a coating layer according to the embodiment.

FIG. 5 is a front view illustrating an example of a cutting tool according to the embodiment.

FIG. 6 is a graph showing a result of reflectance measurement of a coated tool according to a comparative example.

FIG. 7 is a graph showing a result of reflectance measurement of the coated tool according to the embodiment.

FIG. 8 is a graph showing a change in reflectance before and after use of the coated tool according to the comparative example.

FIG. 9 is a graph showing a change in reflectance before and after use of the coated tool according to the example.

FIG. 10 is a graph showing a correlation between a crystallite diameter in a (200) plane of a wear-resistant layer and a primary boundary wear amount.

FIG. 11 is a graph showing a correlation between Vickers hardness of the wear-resistant layer and a secondary boundary wear amount.

FIG. 12 is a graph showing a correlation between a Ti proportion (a) of the wear-resistant layer and the primary boundary wear amount.

FIG. 13 is a graph showing a correlation between an Al proportion (b) of the wear-resistant layer and the primary boundary wear amount.

FIG. 14 is a graph showing a correlation between a Cr proportion (c) of the wear-resistant layer and the primary boundary wear amount.

FIG. 15 is a graph showing a correlation between a peeling load and the secondary boundary wear amount.

FIG. 16 is a graph showing a correlation between a Ti proportion (x) of a cohesion layer and the peeling load.

FIG. 17 is a graph showing a correlation between an Al proportion (y) of the cohesion layer and the peeling load.

FIG. 18 is a graph showing a correlation between the Ti proportion (x) of the cohesion layer and the secondary boundary wear amount.

FIG. 19 is a graph showing a correlation between the Al proportion (y) of the cohesion layer and the secondary boundary wear amount.

FIG. 20 is a graph showing a correlation between a Ti proportion (e) of an intermediate layer and a crater wear depth.

FIG. 21 is a graph showing a correlation between an Al proportion (f) of the intermediate layer and the crater wear depth.

FIG. 22 illustrates images illustrating cutting edge states of three coated tools different in film configurations after a cutting test.

FIG. 23 illustrates images illustrating cutting edge states of eight coated tools different in cohesion layer composition after the cutting test.

FIG. 24 illustrates images illustrating cutting edge states of seven coated tools different in wear-resistant layer composition after the cutting test.

FIG. 25 is a graph showing a relationship between a thickness of the wear-resistant layer and an abrasive wear amount.

FIG. 26 is a graph showing a relationship between a film formation time of the cohesion layer and various wear amounts.

FIG. 27 is a graph showing a relationship between the film formation time of the cohesion layer and a number of impacts until fracture.

FIG. 28 illustrates an image of a cutting edge state of a sample including an intermediate layer, taken from a direction perpendicular to a rake face after the cutting test.

FIG. 29 illustrates an image of a cutting edge state of a sample including no intermediate layer, taken from the direction perpendicular to the rake face after the cutting test.

FIG. 30 is a table summarizing thicknesses of intermediate layers and wear-resistant layers of five samples different in thickness proportions of the intermediate layer and the wear-resistant layer and images illustrating their cutting edge states after the cutting test.

### DESCRIPTION OF EMBODIMENTS

The following is a detailed description of embodiments of a coated tool and a cutting tool according to the present disclosure (hereinafter referred to as “embodiments”) with reference to the drawings. Note that, the coated tool and the cutting tool according to the present disclosure are not limited by the embodiments. Embodiments can be appropriately combined so as not to contradict each other in terms of processing content. In the following embodiments, the same portions are denoted by the same reference signs, and redundant explanations are omitted.

The related art described above has room for further enhancement in terms of facilitating detection of a damaged portion. Therefore, it is expected to provide a coated tool and a cutting tool that enable easy detection of a damaged portion.

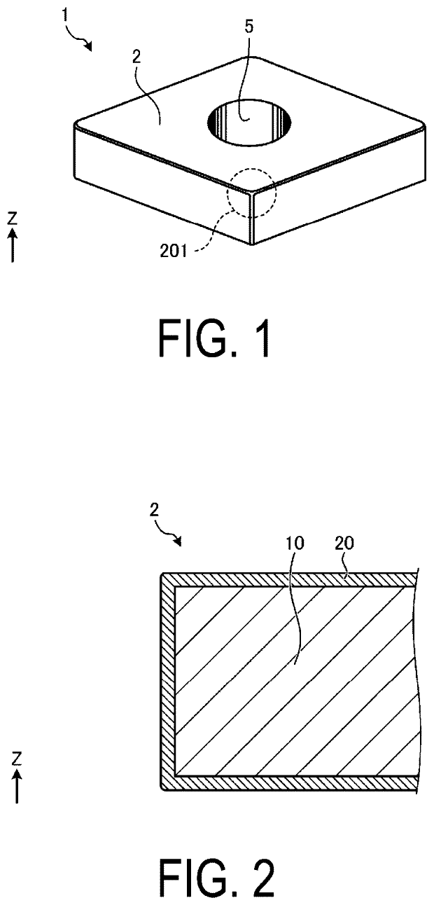

FIG. 1 is a perspective view illustrating an example of a coated tool according to an embodiment. Further, FIG. 2 is a side sectional view illustrating an example of the coated tool according to the embodiment. As illustrated in FIG. 1, a coated tool 1 according to the embodiment includes a tip body 2.

### Tip Body 2

The tip body 2 has a hexagonal shape in which a shape of an upper surface and a lower surface (a surface intersecting the Z-axis illustrated in FIG. 1) is a parallelogram.

One corner portion 201 of the tip body 2 functions as a cutting edge portion. The cutting edge portion has a first surface (for example, an upper surface) and a second surface (for example, a side surface) connected to the first surface. In the embodiment, the first surface functions as a “rake face” for scooping chips generated by cutting, and the second surface functions as a “flank face”. A cutting edge is located on at least a part of a ridge line where the first surface and the second surface intersect with each other, and the coated tool 1 cuts a workpiece through application of the cutting edge to the workpiece.

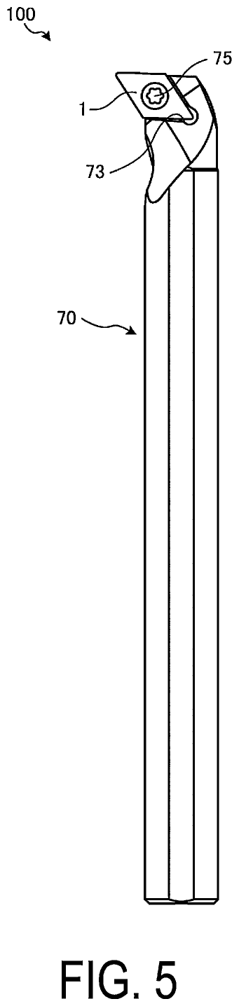

A through hole 5 that vertically penetrates the tip body 2 is located in the center portion of the tip body 2. A screw 75 for attaching the coated tool 1 to a holder 70 to be described below is inserted into the through hole 5 (see FIG. 5).

As illustrated in FIG. 2, the tip body 2 has abase body 10, and a coating layer 20.

### Base Body 10

The base body 10 is made of cemented carbide alloy. Specifically, the base body 10 contains a hard phase containing at least WC (tungsten carbide) and a metallic binder phase containing an iron group element such as Ni (nickel) or Co (cobalt). As an example, the base body 10 is made of WC-based cemented carbide alloy containing hard particles made of WC as a hard phase component and Co as a main component of a binder phase.

### Coating Layer 20

The base body 10 is coated with the coating layer 20 for the purpose of, for example, increasing the wear resistance and heat resistance of the base body 10. In the example in FIG. 2, the coating layer 20 entirely coats the base body 10. However, this example is not be construed in a limiting sense, and the coating layer 20 may be located at least on the base body 10. If the coating layer 20 is located on a first surface (here, the upper surface) of the base body 10, the first surface has high wear resistance and heat resistance. If the coating layer 20 is located on a second surface (here, a side surface) of the base body 10, the second surface has high wear resistance and heat resistance.

### Reflectance of Coating Layer

The coating layer 20 may contain at least one element selected from Group 4a, 5a and 6a elements under the periodic law, Al, Si, B, Y, and Mn, and at least one element selected from C and N. In the coated tool 1 according to the embodiment, a difference between a maximum value and a minimum value of a reflectance of the coating layer 20 in a wavelength range of 400 nm or more and 1500 nm or less may be 15% or less of the maximum value.

The reflectance of the coating layer 20 can be adjusted, for example, by adjusting the composition of the coating layer 20 or adjusting conditions for forming the coating layer 20 and setting a surface roughness. The reflectance of the coating layer 20 may be adjusted by any method as long as the difference between the maximum value and the minimum value of the reflectance of the coating layer 20 can be 15% or less of the maximum value.

The coated tool 1 has a small variation in reflectance with respect to a change in wavelength.

In recent years, a technique has been known for detecting a damaged portion of a tool by imaging at a plurality of wavelengths using a multispectral camera, a hyperspectral camera, or the like. However, since known coated tools have a relatively large variation in reflectance depending on the wavelength, the above-described technique has room for enhancement in terms of accurate detection of a damaged portion.

On the other hand, the coated tool 1 of the embodiment has a small variation in reflectance with respect to the change in wavelength, and thus enables accurate detection of a damaged portion using a multi-spectral camera, a hyper-spectral camera, or the like.

The coated tool 1 according to the embodiment enables easy detection of a portion exhibiting a reflectance different from that of a normal portion as a damaged portion. Therefore, the coated tool 1 of the embodiment enables detection of a damaged portion, for example, using an RGB image taken by a CCD (Charge Coupled Device) camera or the like.

As described above, the coated tool 1 according to the embodiment enables easy detection of a damaged portion not only using an expensive imaging device such as a multispectral camera or a hyperspectral camera but also using a relatively inexpensive imaging device such as a CCD camera. That is, the cost required for detecting the damaged portion can be suppressed to be low.

Preferably, in the coated tool 1 according to the embodiment, a difference 61 between a maximum value R11 and a minimum value R12 of a reflectance of the coating layer 20 in a wavelength range of 400 nm or more and 1500 nm or less may be 10% or less of the maximum value R11. More preferably, the difference 61 may be 8% or less of the maximum value R11 in the coated tool 1 according to the embodiment.

As in the coated tool 1 according to the embodiment, a difference 82 between a maximum value R21 and a minimum value R22 of the reflectance of the coating layer 20 in a wavelength range of 400 nm or more and 800 nm or less in the above-described wavelength range of 400 nm or more and 1500 nm or less may be smaller than a difference 83 between a maximum value R31 and a minimum value R32 of the reflectance of the coating layer 20 in a wavelength range of more than 800 nm and 1500 nm or less.

In the above-described wavelength range of 400 nm or more and 1500 nm or less, the wavelength range of 400 nm or more and 800 nm or less is a so-called visible light region, and thus the damaged portion can be detected even by visual observation of an image. In the case of a relatively small difference 62 in the visible light region, the operation of visually detecting the damaged portion is easy.

In the coated tool 1 according to the embodiment, the difference 63 between the maximum value R31 and the minimum value R32 of the reflectance of the coating layer 20 in the wavelength range of more than 800 nm and 1500 nm or less, in the above-described wavelength range of 400 nm or more and 1500 nm or less, may be 20% or less of the maximum value R31.

In the above-described wavelength range of 400 nm or more and 1500 nm or less, the wavelength range of more than 800 nm and 1500 nm or less is a so-called infrared region, which makes visual detection difficult and requires detection processing using a computer or conversion processing into a visible image using a computer.

If the difference 63 is great, setting of a threshold value for detecting damage in performing the detection processing becomes extremely complicated. This is because, if the threshold value is set in accordance with one of the maximum value R31 and the minimum value R32, the accuracy of the threshold for the other may be lowered.

The above-described conversion processing requires correction processing of the image to the visible light region, and setting of correction conditions becomes extremely complicated. For example, the maximum value R32 is greater than the minimum value R31, and thus is likely to greatly vary depending on the coated tool 1 to be measured or the measurement point. If the correction conditions are set in accordance with the maximum value R31, the information on the difference in minimum value R32 between the damaged portion and a non-damaged portion (normal portion) is likely to be hidden. This is because the detection accuracy may be lowered.

If the difference 83 between the maximum value R31 and the minimum value R32 of the reflectance of the coating layer 20 in the wavelength range of more than 800 nm and 1500 nm or less is 20% or less of the maximum value R31, complicated condition setting is unnecessary for both the detection processing and the conversion processing described above, which can easily increase the detection accuracy.

The reflectance of the coating layer 20 in the wavelength range of 400 nm or more and 1500 nm or less may be greater after use of the coated tool 1 than before use. The reflectance before use refers to the reflectance of the coated tool 1 before the coated tool 1 is used for cutting a workpiece. The reflectance after use refers to the reflectance of the coated tool 1 after the coated tool 1 is used for cutting a workpiece. The term “after use” means a state in which the coated tool 1 has been used to a level at which the coated tool 1 needs to be replaced. As described above, in the coated tool 1 according to the embodiment, the reflectance changes before and after use, and thus a determination as to whether or not the coated tool 1 has been used can easily be made.

The coating layer 20 may include a cohesion layer in contact with the base body 10 and a wear-resistant layer. In this case, the wear-resistant layer may be a single layer.

As described above, the coating layer 20 including the wear-resistant layer composed of a single layer has a reflectance less varying with respect to the change in wavelength than that of, for example, a coating layer including a wear-resistant layer in which nano order layers are laminated. The “laminated wear-resistant layer” is intended to mean a structure in which several tens to several hundreds of layers each having a nano-size thickness are laminated, and the single layer in the “wear-resistant layer composed of a single layer” is intended to mean a structure having a thickness of several hundreds of nanometers or more.

### Form of Damage in Tip Body

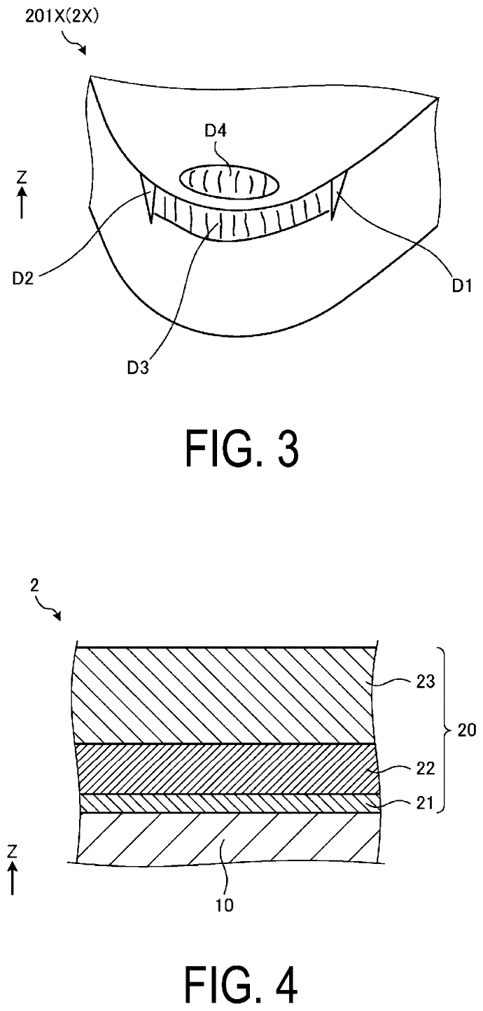

A form of damage that occurs in the tip body will be described with reference to FIG. 3. FIG. 3 is a schematic enlarged view of a corner portion 201X in a tip body 2X according to a reference example.

As illustrated in FIG. 3, for example, the primary boundary wear D1, the secondary boundary wear D2, the abrasive wear D3, and the crater wear D4 may occur in the tip body 2X. The primary boundary wear D1, the secondary boundary wear D2, and the abrasive wear D3 are wear that occurs at a flank face. The crater wear D4 is wear that occurs at the rake face.

The abrasive wear D3 is wear in which surfaces of the tip body 2X are scraped off by foreign matter interposed between the tip body 2X and the workpiece. The abrasive wear D3 may cause an increase in cutting resistance and cutting heat.

The primary boundary wear D1 and the secondary boundary wear D2 are wear that occurs at both ends of the abrasive wear D3, i.e., at a cut boundary. The primary boundary is a boundary portion that comes into contact with a cut surface of the workpiece. The secondary boundary is a boundary portion that comes into contact with a finished surface of the workpiece. The primary boundary wear D1 may cause burrs at the workpiece. The secondary boundary wear D2 may deteriorate the finished surface of the workpiece or change dimensions of the workpiece.

The crater wear D4 is a wear caused by the formation of relatively soft oxides due to oxidation of the surfaces of the tip body 2X at a high temperature. The crater wear D4 may deteriorate chip processability.

The coated tool 1 according to the embodiment can suitably suppress these damage forms, by devising the configuration of the coating layer 20 coating the tip body 2.

An example of a configuration of the coating layer 20 according to the embodiment will be described with reference to FIG. 4. FIG. 4 is a cross-sectional view illustrating an example of the coating layer 20 according to the embodiment.

As illustrated in FIG. 4, the coating layer 20 includes a cohesion layer 21, an intermediate layer 22, and a wear-resistant layer 23. The cohesion layer 21 is a layer in contact with the base body 10. The intermediate layer 22 is located on a surface of the cohesion layer 21. The wear-resistant layer 23 is located on a surface of the intermediate layer 22. That is, the cohesion layer 21, the intermediate layer 22, and the wear-resistant layer 23 are laminated in the order of the cohesion layer 21, the intermediate layer 22, and the wear-resistant layer 23 from the layer closest to the surface of the base body 10.

The cohesion layer 21 is an alloy layer containing TiₓAl_{y}M_{z}. M is at least one metal selected from Group 4a, 5a and 6a elements in the periodic table, and Si. x and y have atomic ratios of 40≤x≤80 and 0≤y≤55, respectively, and x+y+z=100. As an example, the cohesion layer 21 may be made of TiAlWNbSi. z may be 0. That is, the cohesion layer 21 does not necessarily need to contain M. In this case, the cohesion layer 21 may be made of TiAl, for example.

The wear-resistant layer 23 contains TiₐAl_{b}Cr_{c}M_{d} and at least one nonmetal selected from carbon, nitrogen and oxygen. M is at least one metal selected from Group 4a, 5a and 6a elements (excluding Cr) in the periodic table, and Si. a to c have atomic ratios of 15≤a≤40, 55≤b≤75, 10≤c≤20, 0≤d≤15, and a+b+c+d=100. As an example, the wear-resistant layer 23 may be made of TiAlCrWNbSiN. d may be 0. That is, the wear-resistant layer 23 does not necessarily contain M. In this case, the wear-resistant layer 23 may be made of TiAlCrN, for example.

The coated tool 1 according to the embodiment includes the cohesion layer 21 and the wear-resistant layer 23 having the above-described compositions, and thus can suitably suppress the boundary wear.

Factors contributing to suppression of boundary damage include film adhesiveness and plastic deformation resistance of the film. Since the cohesion layer 21 according to the embodiment has high affinity with the base body 10 which is made of cemented carbide alloy, the coating layer 20 having the cohesion layer 21 at an interface with the base body 10 has high adhesiveness with the base body 10. Due to a small crystallite diameter of the wear-resistant layer 23 having the above-described composition, the coating layer 20 including the wear-resistant layer 23 has high plastic deformation resistance.

Therefore, the coating layer 20 including the cohesion layer 21 and the wear-resistant layer 23 can suitably suppress the boundary wear. In particular, the cohesion layer 21 according to the embodiment is effective in suppressing the secondary boundary wear D2, and the wear-resistant layer 23 according to the embodiment is effective in suppressing the primary boundary wear D1.

The intermediate layer 22 contains TiₑAl_{f}M_{g} and at least one nonmetal selected from carbon, nitrogen and oxygen. M is at least one metal selected from Group 4a, 5a and 6a elements (excluding Cr) in the periodic table, and Si. e and f are 0≤e≤55 and 40≤f≤80, respectively, and e+f+g=100. The intermediate layer 22 has high oxidation resistance. Therefore, the coated tool 1 including the intermediate layer 22 can suitably suppress the crater wear D4. As an example, the intermediate layer 22 may be made of TiAlWNbSiN. g may be 0. That is, the intermediate layer 22 does not necessarily contain M. In this case, the intermediate layer 22 may be made of, for example, TiAlN.

The ratio of the metal components in the intermediate layer 22 can be identified by, for example, analysis using an energy dispersive X-ray spectrometer (EDS) attached to a scanning transmission electron microscope (STEM). The ratio of the metal components in the cohesion layer 21 and the wear-resistant layer 23 may also be specified by EDS analysis.

The intermediate layer 22 may be formed using an arc ion plating method (AIP method). The AIP method is a method in which target metals are evaporated by using an arc discharge in a vacuum atmosphere, and are combined with N₂ gas to form metal nitrides. At this time, the bias voltage applied to the base body 10, which is a coated object, may be −30 V or less. The wear-resistant layer 23 may also be formed by the AIP method.

Although an example in which the coating layer 20 includes the cohesion layer 21, the intermediate layer 22, and the wear-resistant layer 23 is shown here, the coating layer 20 does not necessarily include the intermediate layer 22. For example, in case a workpiece in which the crater wear D4 is less likely to occur is used as a target, the coated tool 1 may include the coating layer 20 including the cohesion layer 21 located on a surface of the base body 10 and the wear-resistant layer 23 located on a surface of the cohesion layer 21.

The coating layer 20 may have a thickness of 2.5 μm or more and 10 μm or less. If the thickness of the coating layer 20 is 2.5 μm or more, wear resistance (resistance to abrasive wear) is secured. If the thickness of the coating layer 20 is 10 μm or less, chipping of the coating layer 20 is less likely to occur. Therefore, the coated tool 1 including the coating layer 20 having a thickness of 2.5 μm or more and 10 μm or less is excellent in wear resistance and chipping resistance.

The cohesion layer 21 may have a thickness of 2 nm or more and 8 nm or less. If the thickness of the cohesion layer 21 is 2 nm or more, it is easy to obtain the effect for increasing the film adhesiveness by the cohesion layer 21. Abnormal damage is less likely to occur because film formation unevenness is less likely to occur. On the other hand, if the cohesion layer 21 has a thickness of 8 nm or less, the influence of the relatively soft cohesion layer 21 on the plastic deformation of the coating layer 20 is reduced, and thus the coating layer 20 is less likely to be broken. Therefore, the coated tool 1 including the coating layer 20 including the cohesion layer 21 having a thickness of 2 nm or more and 8 nm or less can further suppress the boundary damage.

The wear-resistant layer 23 may have a crystallite diameter of 200 Å or less. Such a configuration increases the plastic deformation resistance of the coating layer 20, and makes the coating layer 20 less likely to be broken. Therefore, the boundary damage can be further suppressed.

The crystallite diameter of the wear-resistant layer 23 can be controlled by the composition of the wear-resistant layer 23. The crystallite diameter of the wear-resistant layer 23 can be controlled by conditions for forming the wear-resistant layer 23 (such as the bias voltage in the physical vapor deposition method).

The wear-resistant layer 23 may have a Vickers hardness of 28 GPa or more. The secondary boundary wear D2 is generated by, for example, cutting a work-hardened portion with an extremely low cut depth. Therefore, by setting the hardness of the coating layer 20 to 28 GPa or more, the secondary boundary wear D2 can be suitably suppressed even in the case of cutting a workpiece in which work hardening is likely to occur.

The thickness of the intermediate layer 22 may be less than the thickness of the wear-resistant layer 23. If the intermediate layer 22 is thinner than the wear-resistant layer 23, the effect for suppressing the boundary damage by the wear-resistant layer 23 is less likely to decrease. Therefore, by making the thickness of the intermediate layer 22 less than the thickness of the wear-resistant layer 23, the boundary damage can be suitably suppressed.

The coating layer 20 can be located on the base body 10 by using, for example, a physical vapor deposition (PVD) method. For example, in a case where the coating layer 20 is formed by using the above-described vapor deposition method while the base body 10 is held on an inner peripheral surface of the through hole 5, the coating layer 20 can be positioned to entirely cover a surface of the base body 10 except for the inner peripheral surface of the through hole 5.

A configuration of a cutting tool including the coated tool 1 described above is described below with reference to FIG. 5. FIG. 5 is a front view illustrating an example of a cutting tool according to the embodiment.

As illustrated in FIG. 5, a cutting tool 100 according to the embodiment includes the coated tool 1 and a holder 70 for fixing the coated tool 1.

The holder 70 is a rod-like member extending from a first end (upper end in FIG. 5) toward a second end (lower end in FIG. 5). The holder 70 is made of, for example, steel or cast iron. In particular, if steel is used in these members, toughness of the holder 70 is high.

The holder 70 includes a pocket 73 at an end portion on the first end side. The pocket 73 is a portion at which the coated tool 1 is mounted. The pocket 73 has a seating surface intersecting the rotation direction of the workpiece and a restraint side surface inclined with respect to the seating surface. The seating surface is formed with a screw hole into which the screw 75 to be described below is screwed.

The coated tool 1 is located in the pocket 73 of the holder 70 and is mounted on the holder 70 via the screw 75. That is, the screw 75 is inserted into the through hole 5 of the coated tool 1, and the tip of the screw 75 is inserted into the screw hole formed in the seating surface of the pocket 73 such that the screw portions are screwed together. Thus, the coated tool 1 is mounted on the holder 70 such that the cutting edge portion protrudes outward from the holder 70.

In the embodiment, a cutting tool used for so-called turning processing is described as an example. Examples of the turning processing include boring, external turning, and groove-forming. Note that, the cutting tool is not limited to a cutting tool used in turning processing. For example, the coated tool 1 may be used as a cutting tool used for milling processing. Examples of the cutting tool used for milling processing include a milling cutter such as a plain milling cutter, a face milling cutter, a side milling cutter, and a groove milling cutter, and an end mill such as a single-flute end mill, a multi-flute end mill, a taper-blade end mill, and a ball end mill.

### Method for Manufacturing Coating Layer

An example of a method for manufacturing the coating layer 20 according to the embodiment will be described. Note that the manufacturing method of the coated tool according to the embodiment is not limited to the following manufacturing method.

The coating layer may be formed by, for example, a physical vapor deposition method. Examples of the physical vapor deposition method may include an ion plating method and a sputtering method. For example, if the coating layer is formed by an ion plating method, the coating layer may be fabricated by the following method.

An example of a method for manufacturing the cohesion layer will be described. As an example, each of metal targets Ti, Al and M (M is at least one metal selected from Group 4a, 5a and 6a elements in the periodic table, and Si), a composite alloy target, or a sintered body target is prepared.

The target serving as a metal source is vaporized and ionized by arc discharge, glow discharge, or the like, and the ionized metal is vapor-deposited on a surface of the base body. The cohesion layer can be formed by the procedure described above.

The composition of the cohesion layer can be adjusted by independently controlling the voltage and current values at the time of arc discharge and glow discharge applied to a variety of metal targets, for each target. The composition of the cohesion layer can be adjusted by controlling the composition of the metal target, the coating time, and the atmospheric gas pressure. The thickness of the cohesion layer can be adjusted, for example, by controlling the coating time.

A method for manufacturing the wear-resistant layer will then be described. As an example, each of metal targets Ti, Al, Cr and M (M is at least one metal selected from Group 4a, 5a and 6a elements (excluding Cr) in the periodic table, and Si), a composite alloy target, or a sintered body target is prepared.

Then, the target serving as a metal source is vaporized and ionized by arc discharge, glow discharge, or the like. The ionized metal is reacted with a nitrogen (N₂) gas or the like and vapor-deposited on the surface of the base body. The wear-resistant layer can be formed by the procedure described above.

The composition of the wear-resistant layer can be adjusted by independently controlling the voltage and current values at the time of arc discharge and glow discharge applied to a variety of metal targets, for each target. The composition of the wear-resistant layer can be adjusted by controlling the composition of the metal target, the coating time, and the atmospheric gas pressure. The thickness of the wear-resistant layer can be adjusted, for example, by controlling the coating time.

An example of a method for manufacturing the intermediate layer will then be described. As an example, each of metal targets Ti, Al and M (M is at least one metal selected from Group 4a, 5a and 6a elements (excluding Cr) in the periodic table, and Si), a composite alloy target, or a sintered body target is prepared.

Then, the target serving as a metal source is vaporized and ionized by arc discharge, glow discharge, or the like. The ionized metal is reacted with a nitrogen (N₂) gas or the like and vapor-deposited on the surface of the base body. The intermediate layer can be formed by the procedure described above.

The composition of the intermediate layer can be adjusted by independently controlling the voltage and current values at the time of arc discharge and glow discharge applied to a variety of metal targets, for each target. The composition of the intermediate layer can be adjusted by controlling the composition of the metal target, the coating time, and the atmospheric gas pressure. The thickness of the intermediate layer can be adjusted, for example, by controlling the coating time.

### Example

An example of the present disclosure will be specifically described below. The present disclosure is not limited to the following example.

Reflectance of Coating Layer The reflectance was measured, under the following conditions, for a coated tool according to an example including: a cohesion layer made of TiAlNbWSi, in particular, Al₄₉Ti₄₆W₂Nb₂Si₁; an intermediate layer made of TiAlWNbSiN, in particular, Al₄₉Ti₄₆W₂Nb₂Si₁N; and a single wear-resistant layer made of TiAlCrWNbSiN, in particular, Al_{59.5}Ti₂₃Cr₁₅W₁Nb₁Si_{0.5}N. As a comparative example, the reflectance was measured, under the same conditions, for a coated tool including a wear-resistant layer in which two layers different in composition were alternately laminated. The compositions of the two layers in the wear-resistant layer in which the layers were alternately laminated are AlCrN and AlTiWNbSiN, respectively. The other features of the coated tool according to the comparative example are the same as those of the coated tool according to the example.

### Measurement Conditions for Reflectance

Wavelength range: 200 nm or more and 2500 nm or less
Measuring apparatus: ultraviolet-visible near-infrared spectrophotometer V-670 available from JASCO Corporation
Measurement method: total reflectance measurement method
Reflectance calculation method: relative reflectance measurement

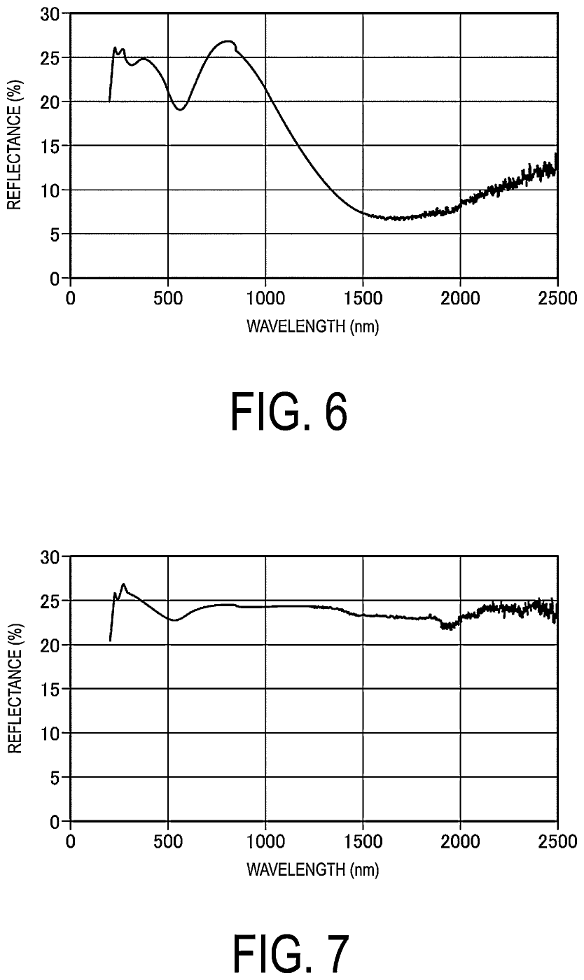

FIG. 6 is a graph showing a result of reflectance measurement of the coated tool according to the comparative example. FIG. 7 is a graph showing a result of reflectance measurement of the coated tool according to the embodiment. The horizontal axis of the graphs shown in FIGS. 6 and 7 indicates the wavelength (nm), and the vertical axis indicates the reflectance (%).

As illustrated in FIG. 6, it can be understood that the coated tool according to the comparative example greatly varies in reflectance with respect to a change in wavelength. To be specific, in the wavelength range of 400 nm or more and 1500 nm or less, the maximum value of the reflectance was 26.9%, the minimum value of the reflectance was 7.3%, and the difference, 19.6% (19.6 points), therebetween was about 72.9% of the maximum value of the reflectance.

On the other hand, as illustrated in FIG. 7, it can be seen that the coated tool according to the example has a very small variation in reflectance with respect to a change in wavelength as compared with the coated tool according to the comparative example. To be specific, in the wavelength range of 400 nm or more and 1500 nm or less, the maximum value of the reflectance was 24.6%, the minimum value of the reflectance was 22.9%, and the difference, 1.7% (1.7 points), therebetween was about 6.9% of the maximum value of the reflectance.

The coated tools according to the examples and the coated tools according to the comparative examples were subjected to measurement of reflectance after being used under the following cutting conditions. The use conditions are as follows. The measurement conditions for the reflectance are the same as the measurement conditions for the reflectance before use described above.

### Cutting Condition

Workpiece: Inconel (registered trademark) 718
Cutting speed (Vc): 30 m/min
Feed (f): 0.1 mm/rev
Cut depth (ap): 0.5 mm
Cutting state: Wet
Tool used: CNMG120408SG
Cutting time: 7.4 min

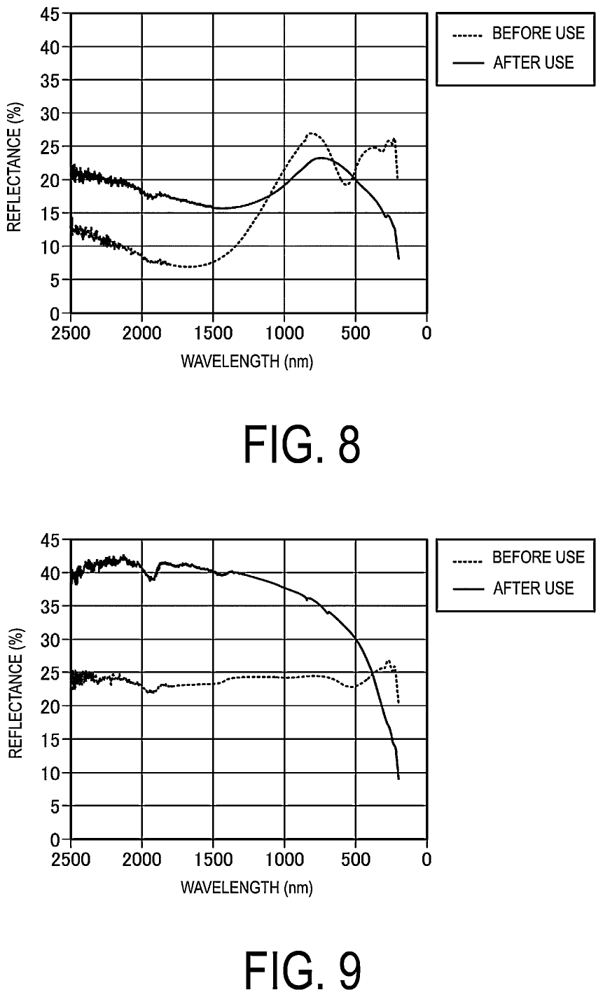

FIG. 8 is a graph showing a change in reflectance before and after use of the coated tool according to the comparative example. FIG. 9 is a graph showing a change in reflectance before and after use of the coated tool according to the example. In FIGS. 8 and 9, the reflectance before use is indicated by a broken line, and the reflectance after use is indicated by a solid line. The results of the reflectance after use illustrated in FIGS. 8 and 9 are the same as the results illustrated in FIGS. 6 and 7.

As illustrated in FIGS. 8 and 9, it can be seen that the coated tool according to the comparative example has a relatively less change in reflectance before and after use, whereas the coated tool according to the example has a great change in reflectance before and after use as compared with the coated tool according to the comparative example. To be specific, in the range of 400 nm or more and 1500 nm or less, the coated tool according to the example has a higher reflectance after use than before use. In the coated tool according to the example, the range from the minimum value to the maximum value of the reflectance before use and the range from the minimum value to the maximum value of the reflectance after use do not overlap with each other in the range of 400 nm or more and 1500 nm or less. As is clear from this result, a determination as to whether or not the coated tool according to the example has been used can easily be made. The coated tool according to the example enables easy detection of a portion exhibiting a reflectance different from that of a normal portion as a damaged portion.

### Composition of Wear-Resistant Layer

A plurality of samples (Samples No. 1 to No. 15) having different composition ratios (a to d) of the wear-resistant layer were prepared for the coating layer including the wear-resistant layer having the composition of TiₐAl_{b}Cr_{c}M_{d}, the cohesion layer having the composition of TiₓAl_{y}M_{z}, and the intermediate layer having the composition of TiₑAl_{f}M_{g}. The composition ratios (a to d) of the wear-resistant layers and the compositions of M in Samples No. 1 to No. 15 are as shown in Table 1. The compositions of the cohesion layer in Samples No. 1 to No. 15 are all Al₄₉Ti₄₆M₅, specifically, Al₄₉Ti₄₆W₂Nb₂Si₁. The compositions of the intermediate layer in Samples No. 1 to No. 15 are Al₄₉Ti₄₆M₅N, specifically, Al₄₉Ti₄₆W₂Nb₂Si₁N. The thicknesses of the wear-resistant layer, the cohesion layer, and the intermediate layer in Samples No. 1 to No. 15 are 4.5 μm, 5 nm, and 2 μm, respectively.

For the prepared samples No. 1 to No. 15, the crystallite diameter of the (200) plane, the hardness of the wear-resistant layer, the primary boundary wear amount, and the secondary boundary wear amount were measured. The crystallite diameter of the (200) plane was measured using XRD. For the hardness (Vickers hardness) of the wear-resistant layer, a measurement range was set from the surface of the wear-resistant layer (i.e., the surface of the coating layer) to a depth corresponding to 20% of the thickness of the wear-resistant layer, and the hardness of each sample was measured using a microindentation hardness tester “ENT-1100b/a” (available from Elionix Co., Ltd.) under an indentation load of 30 N of an indenter. The primary boundary wear amount and the secondary boundary wear amount were measured from images obtained by imaging the primary boundary and the secondary boundary of each sample after the cutting test was performed under the following conditions.

### Cutting Test Conditions

Workpiece: Inconel (registered trademark) 718
Cutting speed (Vc): 30 m/min
Feed (f): 0.10 mm/rev
Cut depth (ap): 0.5 mm
Cutting state: Wet
Tool used: CNMG120408SG
Cutting time: 7.4 min

TABLE 1

| | | | | | | (200) | | Primary | Secondary |
|---|---|---|---|---|---|---|---|---|---|
| | | | | | | Crystallite | Vickers | boundary | boundary |
| SAMPLE | | | | | Composition | diameter | hardness | wear amount | wear amount |
| NO. | Ti(a) | Al(b) | Cr(c) | M(d) | of M | (Å) | (GPa) | (mm) | (mm) |
| 1 | 15 | 55 | 20 | 10 | W₂Nb₂Si₁ | 172 | 29.8 | 0.082 | 0.091 |
| 2 | 23 | 50 | 20 | 7 | W₆Nb₆Si₃ | 160 | 26.8 | 0.069 | 0.186 |
| 3 | 23 | 59.5 | 15 | 2.5 | W₁Nb_{0.5}Si_{0.5} | 89 | 30.2 | 0.043 | 0.055 |
| 4 | 25 | 65 | 10 | 0 | — | 177 | 26.3 | 0.047 | 0.122 |
| 5 | 25 | 55 | 15 | 5 | W₂Nb₂Si₁ | 122 | 30.2 | 0.061 | 0.058 |
| 6 | 20 | 55 | 10 | 15 | W₆Nb₆Si₃ | 157 | 29.3 | 0.063 | 0.070 |
| 7 | 32 | 56 | 10 | 2 | W₁Nb_{0.5}Si_{0.5} | 143 | 30.1 | 0.099 | 0.103 |
| 8 | 30 | 60 | 5 | 5 | Nb₅ | 233 | 28 | 0.076 | 0.158 |
| 9 | 15 | 75 | 10 | 0 | — | 265 | 30.2 | 0.080 | 0.111 |
| 10 | 0 | 55 | 25 | 20 | W₁₀Nb₁₀ | 299 | 26.8 | 0.129 | 0.186 |
| 11 | 20 | 55 | 25 | 0 | — | 255 | 26.3 | 0.081 | 0.202 |
| 12 | 18 | 69 | 8 | 5 | W₅ | 215 | 27.4 | 0.093 | 0.196 |
| 13 | 18 | 72 | 5 | 5 | Si₅ | 146 | 24.5 | 0.101 | 0.260 |
| 14 | 46 | 49 | 0 | 5 | W₂Nb₂Si₁ | 229 | 29.6 | 0.133 | 0.136 |
| 15 | 50 | 50 | 0 | 0 | — | 230 | 26.3 | 0.122 | 0.220 |

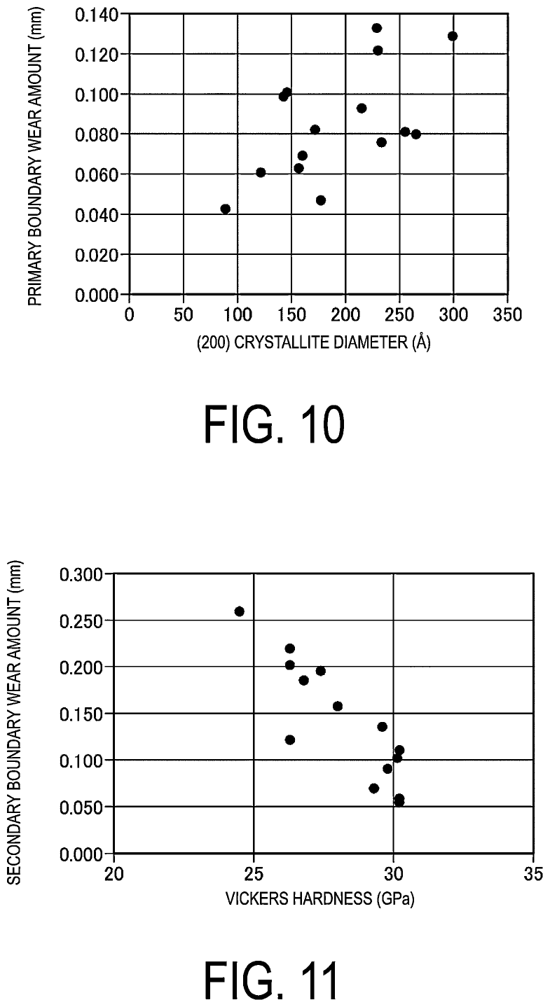

FIG. 10 is a graph showing a correlation between the crystallite diameter in the (200) plane of the wear-resistant layer and the primary boundary wear amount. The horizontal axis of the graph shown in FIG. 10 indicates the crystallite diameter (Å) of the (200) plane, and the vertical axis indicates the secondary boundary wear amount (mm).

As shown in FIG. 10, the primary boundary wear amount was likely to decrease as the crystallite diameter of the (200) plane in the wear-resistant layer decreased. From this result, it can be seen that the crystallite diameter of the wear-resistant layer is preferably smaller. Specifically, the crystallite diameter of the wear-resistant layer is preferably 200 Å or less. That is, among Samples No. 1 to No. 15, Samples No. 1 to No. 7 and No. 13 in which the crystallite diameter of the (200) plane is 200 Å or less are effective in suppressing the primary boundary damage.

FIG. 11 is a graph showing a correlation between the Vickers hardness of the wear-resistant layer and the secondary boundary wear amount. The horizontal axis of the graph shown in FIG. 11 indicates the Vickers hardness (GPa) of the wear-resistant layer, and the vertical axis indicates the secondary boundary wear amount (mm).

As shown in FIG. 11, the secondary boundary wear amount was likely to increase as the Vickers hardness of the wear-resistant layer increased. It can be seen that if the Vickers hardness of the wear-resistant layer is 28 GPa or more, the secondary boundary wear amount is suitably suppressed. That is, it can be seen that, among Samples No. 1 to No. 15, Samples No. 1, No. 3, and No. 5 to No. 9 having a Vickers hardness of 28 GPa or more are effective in suppressing the secondary boundary damage.

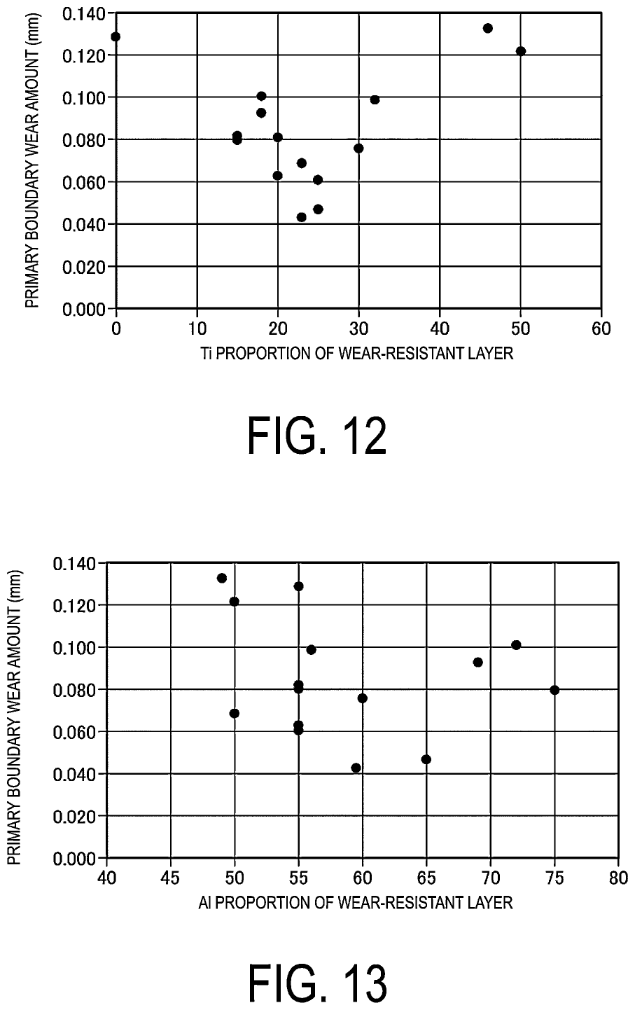

FIG. 12 is a graph showing a correlation between the Ti proportion (a) of the wear-resistant layer and the primary boundary wear amount. The horizontal axis of the graph shown in FIG. 12 indicates the Ti proportion of the wear-resistant layer, and the vertical axis indicates the primary boundary wear amount (mm).

From the results illustrated in FIG. 12, it can be seen that the samples in which the Ti proportion (a) is 15≤a≤40, specifically, Samples No. 1 to No. 9 and No. 11 to No. 13 are effective in suppressing the primary boundary damage. The samples in which the Ti proportion (a) is 20≤a≤30, specifically, Samples No. 1 to No. 6, No. 8, No. 9, and No. 11 to No. 13 are particularly effective in suppressing the primary boundary damage.

FIG. 13 is a graph showing a correlation between the Al proportion (b) of the wear-resistant layer and the primary boundary wear amount. The horizontal axis of the graph shown in FIG. 13 is the Al proportion of the wear-resistant layer, and the vertical axis indicates the primary boundary wear amount (mm).

From the results illustrated in FIG. 13, it can be seen that the samples in which the Al proportion (b) is 55≤b≤75, specifically, Samples No. 1 and No. 3 to No. 13 are effective in suppressing the primary boundary damage. The samples in which the Al proportion (b) is 55≤b≤70, specifically, Samples No. 1, No. 3 to No. 8, and No. 10 to No. 12 are particularly effective in suppressing the primary boundary damage.

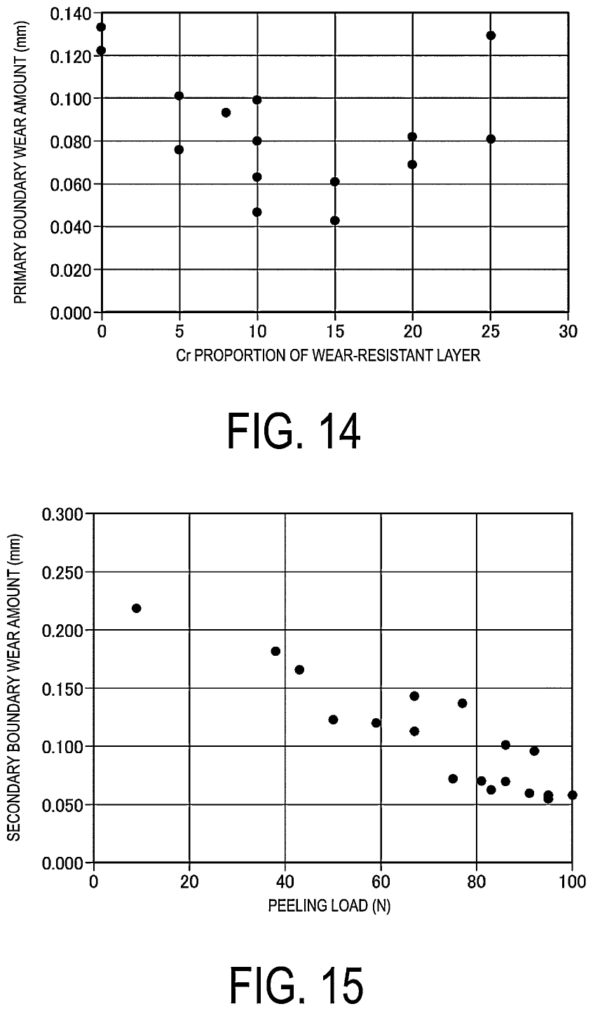

FIG. 14 is a graph showing a correlation between the Cr proportion (c) of the wear-resistant layer and the primary boundary wear amount. The horizontal axis of the graph shown in FIG. 14 is the Cr proportion of the wear-resistant layer, and the vertical axis indicates the primary boundary wear amount (mm).

From the results illustrated in FIG. 14, it can be seen that the samples in which the Cr proportion (c) is 5≤c≤20, specifically, Samples No. 1 to No. 12 are effective in suppressing the primary boundary damage. The samples in which the Cr proportion (c) is 10≤c≤20, specifically, Samples No. 1 to No. 7 and No. 9 are particularly effective in suppressing the primary boundary damage.

In order to effectively suppress the secondary boundary damage in addition to the primary boundary damage, the composition ratios (a to d) of the wear-resistant layer having the composition of TiₐAl_{b}Cr_{c}M_{d} are preferably in the range of 15≤a≤40, 55≤b≤75, 10≤c≤20, 0≤d≤15, respectively (provided that a+b+c+d=100). More specifically, the composition ratios (a to d) of the wear-resistant layer are preferably 20≤a≤30, 55≤b≤70, 15≤c≤20, and 2.5≤d≤15, respectively.

### Composition of Cohesion Layer

A plurality of samples (Samples No. 21 to No. 38) having different composition ratios (x to z) of the cohesion layer were prepared for the coating layer including the wear-resistant layer having the composition of TiₐAl_{b}Cr_{c}M_{d}, the cohesion layer having the composition of TiₓAl_{y}M_{z}, and the intermediate layer having the composition of TiₑAl_{f}M_{g}. The composition ratios (x to z) of the cohesion layers and the compositions of M in Samples No. 21 to No. 38 are as shown in Table 2. The compositions of the wear-resistant layer in Samples No. 21 to No. 38 were Al_{59.5}Ti₂₃Cr₁₅W₁Nb₁Si_{0.5}N. The compositions of the intermediate layer in Sample Nos. 21 to 38 were Al₄₉Ti₄₆M₅N, specifically, Al₄₉Ti₄₆W₂Nb₂Si₁N. The thicknesses of the wear-resistant layer, the cohesion layer, and the intermediate layer in Samples No. 21 to No. 38 are 4.5 μm, 5 nm, and 2 μm, respectively.

The thickness of the cohesion layer, the peeling load, the primary boundary wear amount, and the secondary boundary wear amount were measured for the prepared samples No. 21 to No. 38. The thickness of the cohesion layer was measured from an image obtained by observing the cohesion layer using a transmission electron microscope (TEM). Specifically, an average value of measurement results at three points for each of three visual fields, that is, nine points in total was used as the thickness of the cohesion layer. The peeling load was measured by a scratch test. The scratch tests were performed by using a diamond indenter having a tip shape with a curvature radius R of 200 μm at a rate of 10 mm/min and a load rate of 100 N per minute. In the scratch tests, the load when peeling occurred (peeling load) was evaluated as adhesion force. The scratch tests indicate that as the critical load is greater, peeling is less likely to occur, that is, adhesion force is greater. The primary boundary wear and the secondary boundary wear were measured in the same and/or similar manner as the case with Samples No. 1 to No. 15 described above. The results of these measurements are shown in Table 2.

TABLE 2

| | | | | | | | | Primary | Secondary |
|---|---|---|---|---|---|---|---|---|---|
| SAMPLE | | | | Composition | Al/ | Cohesion layer | Peeling | boundary wear | boundary wear |
| NO. | Ti(x) | Al(y) | M(z) | of M | (TiAlM) | thickness (nm) | load (N) | amount (mm) | amount (mm) |
| 21 | 80 | 0 | 20 | Si₂₀ | 0.00 | 5.00 | 95 | 0.055 | 0.058 |
| 22 | 70 | 30 | 0 | — | 0.30 | 5.00 | 75 | 0.063 | 0.072 |
| 23 | 50 | 50 | 0 | — | 0.50 | 5.00 | 91 | 0.052 | 0.060 |
| 24 | 46 | 49 | 5 | W₂Nb₂Si₁ | 0.49 | 5.00 | 95 | 0.043 | 0.055 |
| 25 | 49 | 41 | 10 | Cr₁₀ | 0.41 | 5.00 | 83 | 0.060 | 0.063 |
| 26 | 80 | 0 | 20 | Cr₂₀ | 0.00 | 5.00 | 100 | 0.046 | 0.058 |
| 27 | 0 | 0 | 100 | Cr₁₀₀ | 0.00 | 5.00 | 92 | 0.116 | 0.096 |
| 28 | 0 | 25 | 75 | Cr₇₅ | 0.25 | 5.00 | 86 | 0.122 | 0.101 |
| 29 | 0 | 50 | 50 | Cr₅₀ | 0.50 | 5.00 | 67 | 0.125 | 0.113 |
| 30 | 0 | 71 | 29 | Cr₂₉ | 0.71 | 5.00 | 43 | 0.094 | 0.166 |
| 31 | 25 | 68 | 7 | Cr₇ | 0.68 | 5.00 | 67 | 0.099 | 0.143 |
| 32 | 23 | 59.5 | 17.5 | Cr₁₅W₁Nb₁Si_{0.5} | 0.60 | 5.00 | 77 | 0.092 | 0.137 |
| 33 | 20 | 80 | 0 | — | 0.80 | 5.00 | 38 | 0.102 | 0.182 |
| 34 | 80 | 10 | 10 | Cr₁₀ | 0.10 | 5.00 | 81 | 0.060 | 0.070 |
| 35 | 0 | 100 | 0 | — | 1.00 | 5.00 | 9 | 0.135 | 0.219 |
| 36 | 70 | 0 | 30 | Cr₃₀ | 0.00 | 5.00 | 86 | 0.088 | 0.070 |
| 37 | 39 | 41 | 20 | Nb₂₀ | 0.41 | 5.00 | 50 | 0.110 | 0.123 |
| 38 | 85 | 0 | 15 | W₁₅ | 0.00 | 5.00 | 59 | 0.133 | 0.120 |

FIG. 15 is a graph showing a correlation between the peeling load and the secondary boundary wear amount. The horizontal axis of the graph shown in FIG. 15 is the peeling load (N), and the vertical axis indicates the secondary boundary wear amount (mm).

As illustrated in FIG. 15, it can be seen that as the peeling load increases, that is, as the adhesion force increases, the secondary boundary wear amount decreases, that is, the secondary boundary damage is suppressed.

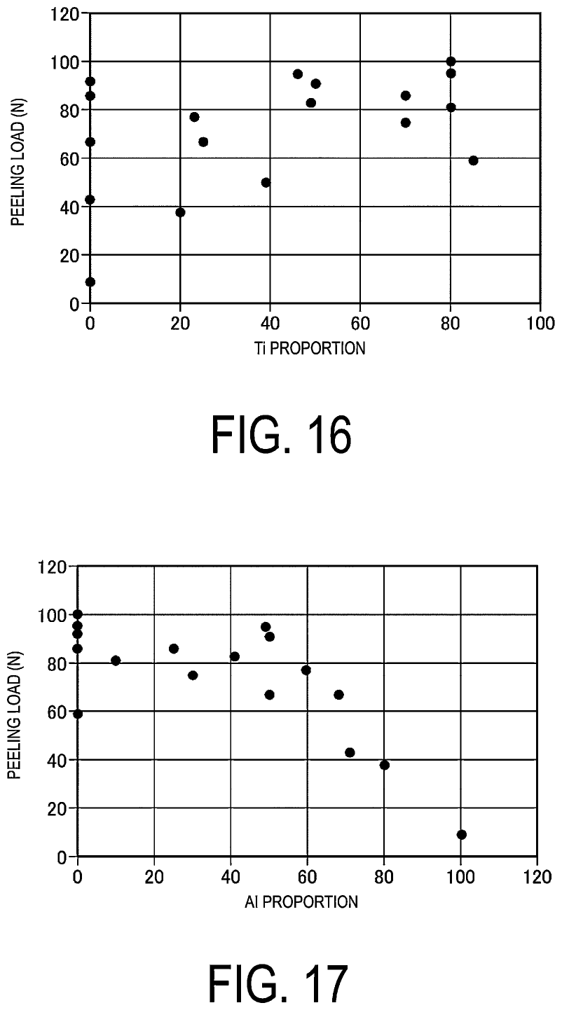

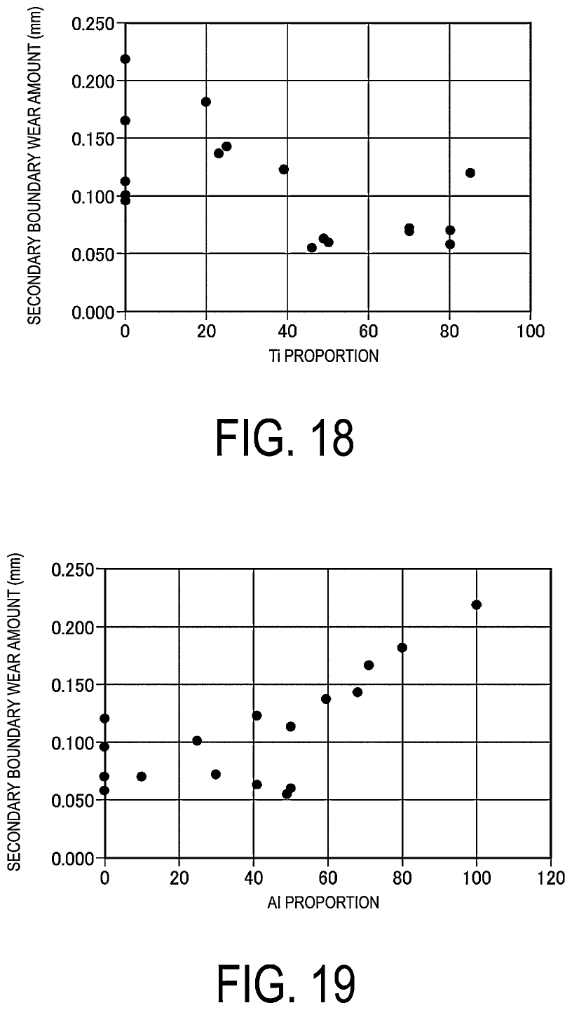

FIG. 16 is a graph showing a correlation between the Ti proportion (x) of the cohesion layer and the peeling load. FIG. 17 is a graph showing a correlation between the Al proportion (y) of the cohesion layer and the peeling load. FIG. 18 is a graph showing a correlation between the Ti proportion (x) of the cohesion layer and the secondary boundary wear amount. FIG. 19 is a graph showing a correlation between the Al proportion (y) of the cohesion layer and the secondary boundary wear amount.

From the results in FIG. 15 and the results in FIGS. 16 to 19, in order to effectively suppress the secondary boundary damage, it is preferable that the Ti proportion of the cohesion layer be relatively high and that the Al proportion be relatively low. Specifically, the composition ratios (x to z) of the cohesion layer are preferably within ranges of 40≤x≤80 and 0≤y≤55 (provided that x+y+z=100).

### Composition of Intermediate Layer

A plurality of samples (Samples No. 41 to No. 49) having different composition ratios (e to g) of the intermediate layer were prepared for the coating layer including the wear-resistant layer having the composition of TiₐAl_{b}Cr_{c}M_{d}, the cohesion layer having the composition of TiₓAl_{y}M_{z}, and the intermediate layer having the composition of TiₑAl_{f}M_{g}. The composition ratios (e to g) of the intermediate layers and the compositions of M in Samples No. 41 to No. 49 are as shown in Table 3. The composition of the wear-resistant layer is Al_{59.5}Ti₂₃Cr₁₅W₁Nb₁Si_{0.5}N. The composition of the cohesion layer is Al₄₉Ti₄₆M₅, specifically, Al₄₉Ti₄₆W₂Nb₂Si₁. The thicknesses of the wear-resistant layer, the cohesion layer, and the intermediate layer in Samples No. 41 to No. 49 are 2.5 μm, 5 nm, and 2 μm, respectively.

For the prepared samples No. 41 to No. 49, the crater wear depth was measured. The crater wear depth was measured from an image obtained by imaging the rake face of each sample after the cutting test was performed under the same and/or similar conditions as in the measurement of the primary boundary wear amount and the secondary boundary wear amount in the wear-resistant layer and the cohesion layer. The measurement results are also shown in Table 3.

TABLE 3

| | | | | Composition | Crater wear |
|---|---|---|---|---|---|
| SAMPLE NO. | Ti(e) | Al(f) | M(g) | of M | depth (mm) |
| 41 | 60 | 35 | 5 | W₂Nb₂Si₁ | 0.093 |
| 42 | 65 | 35 | 0 | — | 0.099 |
| 43 | 46 | 49 | 5 | W₂Nb₂Si₁ | 0.034 |
| 44 | 50 | 30 | 20 | Si₂₀ | 0.064 |
| 45 | 15 | 85 | 0 | — | 0.063 |
| 46 | 25 | 75 | 0 | — | 0.045 |
| 47 | 30 | 65 | 5 | W₂Nb₂Si₁ | 0.037 |
| 48 | 20 | 80 | 0 | — | 0.05 |
| 49 | 50 | 50 | 0 | — | 0.046 |

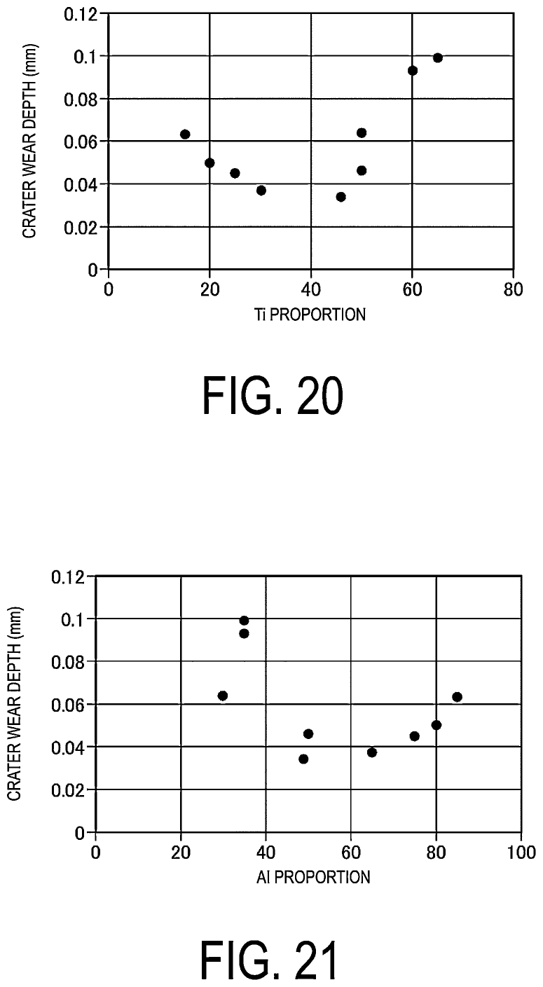

FIG. 20 is a graph showing a correlation between the Ti proportion (e) of the intermediate layer and the crater wear depth. The horizontal axis of the graph shown in FIG. 20 is the Ti proportion of the intermediate layer, and the vertical axis indicates the crater wear depth (mm). FIG. 21 is a graph showing a correlation between the Al proportion (f) of the intermediate layer and the crater wear depth. The horizontal axis of the graph shown in FIG. 21 is the Al proportion of the intermediate layer, and the vertical axis indicates the crater wear depth (mm).

From the results illustrated in FIGS. 20 and 21, in order to effectively suppress the crater wear, the composition ratios (e to g) of the intermediate layer are preferably in the range of 0≤e≤55 and 40≤f≤80 (provided that e+f+g=100).

Comparison of Boundary Wear Depending on Difference in Film Configuration Coated tools including a coating layer composed of a cohesion layer and a single wear-resistant layer on a surface of a base body (Samples No. 3, No. 24, and No. 43 described above. Note that Samples No. 3, No. 24, and No. 43 are the same samples), coated tools including a coating layer composed of only a single wear-resistant layer on the surface of the base body, and coated tools including a wear-resistant layer in which two layers having different compositions were alternately laminated on the surface of the base body were prepared. The base body contains a hard phase containing WC and a metallic binder phase containing an iron group element. The composition of the cohesion layer is Al₄₉Ti₄₆W₂Nb₂Si₁. The composition of the single wear-resistant layer is Al_{59.5}Ti₂₃Cr₁₅W₁Nb₁Si_{0.5}N. The compositions of the two layers in the wear-resistant layer in which the layers were alternately laminated are AlCrN and AlTiWNbSiN, respectively.

A cutting test was performed using the three prepared samples. Conditions are as follows.

### Cutting Test Conditions

Workpiece: Inconel (registered trademark) 718
Cutting speed (Vc): 30 m/min
Feed (f): 0.1 mm/rev
Cut depth (ap): 0.5 mm
Cutting state: Wet
Tool used: CNMG120408SG

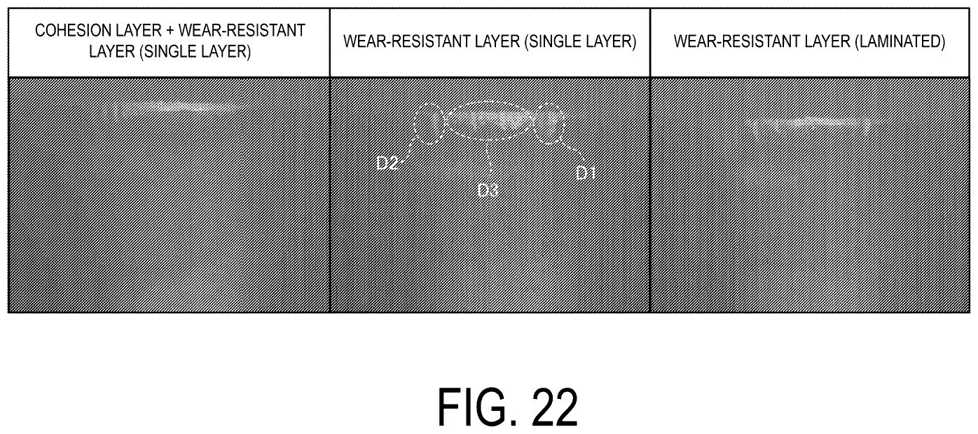

FIG. 22 illustrates cutting edge states after cutting for 14.8 minutes under the above cutting conditions. FIG. 22 illustrates images illustrating cutting edge states of three coated tools different in film configurations after the cutting test.

As illustrated in FIG. 22, the primary boundary wear and the secondary boundary wear were reduced in the coated tool having the film configuration of “the cohesion layer and the single wear-resistant layer”, as compared with the coated tool having the film configuration of “only the single wear-resistant layer” and the coated tool having the film configuration of “the wear-resistant layer in which two layers were alternately laminated”. From this result, it can be seen that the film configuration of “the cohesion layer and the single wear-resistant layer” is effective in suppressing the boundary wear.

The abrasive wear was also reduced in the coated tool having the film configuration of “the cohesion layer and the single wear-resistant layer”, as compared with the coated tool having the film configuration of “only the single wear-resistant layer” and the coated tool having the film configuration of “the wear-resistant layer in which two layers were alternately laminated”. From this result, it can be seen that the film configuration of “the cohesion layer and the single wear-resistant layer” is effective also in suppressing the abrasive wear.

### Composition of Cohesion Layer

For the coated tool having the film configuration of “the cohesion layer and the single wear-resistant layer”, a plurality of samples having different compositions of the cohesion layer were prepared. The compositions of the cohesion layer are Ti, Cr, Al, TiCr, AlCr, TiAl, TiAlCr and TiAlNbWSi. TiAlNbWSi is in particular Al₄₉Ti₄₆W₂Nb₂Si₁. A cutting test was performed on the plurality of prepared samples under the same and/or similar conditions as described above. The compositions of the wear-resistant layer of all the samples are TiAlNbWSiN, i.e., Al_{59.5}Ti₂₃Cr₁₅W₁Nb₁Si_{0.5}N.

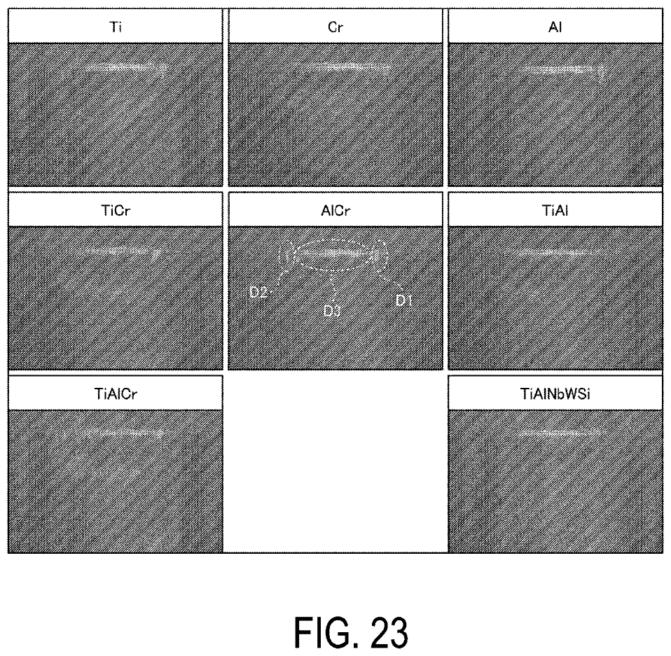

FIG. 23 illustrates cutting edge states after cutting for 7.4 minutes under the above cutting conditions. FIG. 23 illustrates images illustrating cutting edge states of eight coated tools different in cohesion layer composition after the cutting test.

As illustrated in FIG. 23, the wear state was changed depending on the composition of the cohesion layer. To be specific, it was found that the primary boundary wear, the secondary boundary wear, and the abrasive wear were suppressed in the coated tools including the cohesion layer made of TiAl and the coated tools including the cohesion layer made of TiAlNbWSi, as compared with the coated tools including the cohesion layers of other compositions.

### Composition of Wear-Resistant Layer

For the coated tool having the film configuration of “the cohesion layer and the single wear-resistant layer”, a plurality of samples having different compositions of the wear-resistant layer were prepared. The compositions of the wear-resistant layer are TiAlN, TiAlSiN, TiAlNbN, TiAlWN, TiAlCrN, TiAlWNbSiN and TiAlCrWNbSiN, respectively. To be specific, TiAlCrWNbSiN was Al_{59.5}Ti₂₃Cr₁₅W₁Nb₁Si_{0.5}N. A cutting test was performed on the plurality of prepared samples under the same and/or similar conditions as described above. The compositions of the cohesion layer of all the sample are TiAlNbWSi, specifically, Al₄₉Ti₄₆W₂Nb₂Si₁.

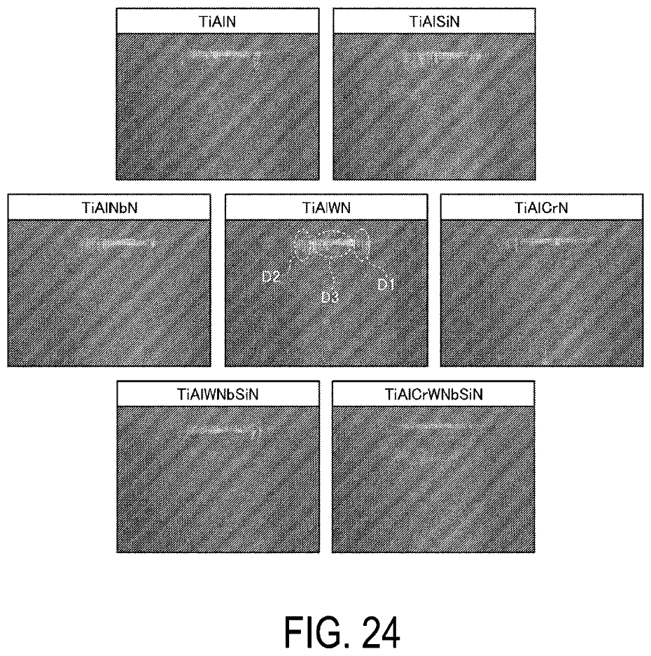

FIG. 24 illustrates cutting edge states after cutting for 7.4 minutes under the above cutting conditions. FIG. 24 illustrates images illustrating cutting edge states of seven coated tools different in wear-resistant layer composition after the cutting test.

As illustrated in FIG. 24, the wear state was changed depending on the composition of the wear-resistant layer. To be specific, it was found that the coated tools including the wear-resistant layer made of TiAlCrWNbSiN are suppressed in the primary boundary wear, the secondary boundary wear, and the abrasive wear, as compared with the coated tools including the wear-resistant layer of other compositions.

### Wear-Resistant Layer Thickness

For a coated tool including: a cohesion layer made of TiAlNbWSi, in particular, Al₄₉Ti₄₆W₂Nb₂Si₁; and a wear-resistant layer made of TiAlCrWNbSiN, in particular, Al_{59.5}Ti₂₃Cr₁₅W₁Nb₁Si_{0.5}N, a plurality of samples including wear-resistant layers with different thicknesses were prepared. The thicknesses of the coating layers of the samples were 1.7 μm, 3.1 μm, 3.4 μm, 4.1 μm, 4.7 μm, 5.3 μm and 5.8 μm, respectively. The thicknesses of the cohesion layers were the same in all the samples. Therefore, the thicker the coating layer is, the thicker the wear-resistant layer is. The thickness of the cohesion layer is the 5 nm on average.

A cutting test was performed on the plurality of prepared samples under the same and/or conditions as described above. The length of the abrasive wear in the thickness direction of the coating layer of each sample (hereinafter referred to as “abrasive wear amount”) was measured using an image illustrating the cutting edge state of each sample after the test. The cutting time in the cutting test is 15 minutes.

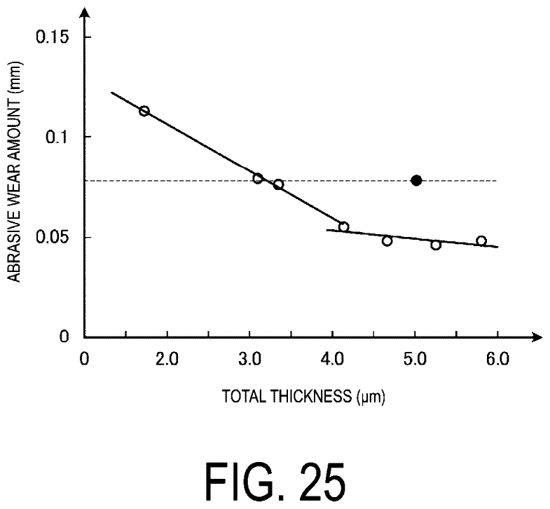

FIG. 25 is a graph showing a relationship between the thickness of the wear-resistant layer and the abrasive wear amount. The horizontal axis of the graph shown in FIG. 25 indicates the total thickness of the coating layer, that is, the sum of the thicknesses of the cohesion layer and the wear-resistant layer. The vertical axis of the graph illustrated in FIG. 25 indicates the abrasive wear amount.

A commercially available coated tool including a coating layer having a thickness of 5 μm was subjected to a cutting test under the same and/or similar cutting conditions as above, and then the abrasive wear amount was measured. The result is shown by a black circle in FIG. 25.

As shown in FIG. 25, as the thickness of the wear-resistant layer increased, the abrasive wear amount decreased. For example, in order to suppress the abrasive wear amount to less than 1 mm, the coating layer is preferably 2.5 μm or thicker. By setting the total thickness of the coating layer to about 3 μm, the abrasive wear amount is about the same as that of the commercially available product. From the result of FIG. 25, in order to reduce the abrasive wear amount as much as possible, the total thickness of the coating layer is preferably set to 4.1 μm or more. On the other hand, if the thickness of the coating layer is more than 10 μm, film formation becomes difficult. Therefore, the thickness of the coating layer is preferably 2.5 μm or more and 10 μm or less, more preferably 4.1 μm or more and 10 μm or less.

### Thickness of Cohesion Layer

For a coated tool including: a cohesion layer made of TiAlNbWSi, in particular, Al₄₉Ti₄₆W₂Nb₂Si₁; and a wear-resistant layer made of TiAlCrWNbSiN, in particular, Al_{59.5}Ti₂₃Cr₁₅W₁Nb₁Si_{0.5}N, a plurality of samples including cohesion layers with different thicknesses were prepared. The thickness of the cohesion layer can be controlled by adjusting the film formation time of the cohesion layer, and the thickness of the cohesion layer increases as the film formation time increases. The film formation times of the cohesion layers of the samples are 0 min, 0.7 min, 1.5 min, and 3 min, respectively. The thicknesses of the cohesion layers of the samples are 0 nm, 1 nm, 5 nm, and 10 nm, respectively.

A cutting test was performed on the plurality of prepared samples under the same and/or similar conditions as described above. The length of the primary boundary wear (hereinafter referred to as “primary boundary wear amount”), the length of the secondary boundary wear (hereinafter referred to as “secondary boundary wear amount”), and the length of the abrasive wear (hereinafter referred to as “abrasive wear amount”) in the thickness direction of the coating layer of each sample were measured using an image illustrating the cutting edge state of each sample after the test. The cutting time in the cutting test is 7.4 minutes.

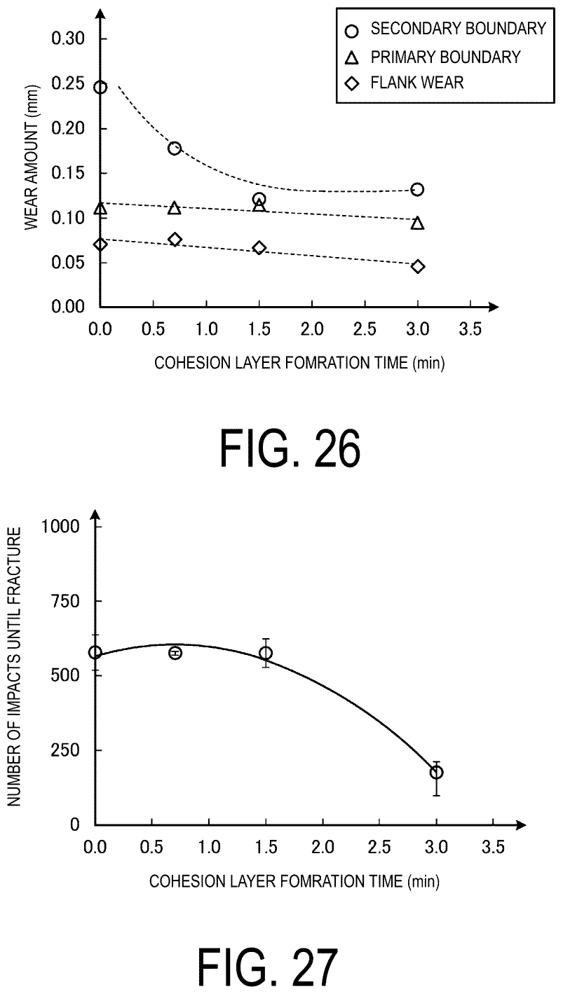

FIG. 26 is a graph showing a relationship between the film formation time of the cohesion layer and various wear amounts. As illustrated in FIG. 26, as the film formation time of the cohesion layer increased, that is, as the thickness of the cohesion layer increased, the various wear amounts were likely to be reduced more. This tendency was particularly remarkable in the secondary boundary wear. From the results illustrated in FIG. 26, in order to suppress all of the primary boundary wear, the secondary boundary wear, and the flank wear, the cohesion layer is preferably 2 nm or more and 8 nm or less.

A fracture resistance test was performed on the same samples as the samples illustrated in FIG. 26, that is, the samples in which the film formation times of the cohesion layer were set to 0 min, 0.7 min, 1.5 min, and 3 min, respectively. Conditions are as follows.

### Fracture Resistance Test

Workpiece: SUS304
Cutting speed: 150 m/min
Feed: 0.2 mm/rev
Cut depth: 1 mm
Cutting state: Wet
Tool used: CNMG120408SG
Evaluation Method: Number of impacts (times) until fracture

FIG. 27 is a graph showing a relationship between the film formation time of the cohesion layer and the number of impacts until fracture. As illustrated in FIG. 27, it can be seen that, when the film formation time exceeds 1.5 min, the fracture resistance decreases. Therefore, from the results illustrated in FIGS. 26 and 27, the thicknesses of the cohesion layers are preferably 2 nm or more and 8 nm or less. The thickness of the cohesion layer can be derived from the film formation time.

### Intermediate Layer

For a coated tool including: a cohesion layer made of TiAlNbWSi, in particular, Al₄₉Ti₄₆W₂Nb₂Si₁; and a wear-resistant layer made of TiAlCrWNbSiN, in particular, Al_{59.5}Ti₂₃Cr₁₅W₁Nb₁Si_{0.5}N, a sample including an intermediate layer between a cohesion layer and a wear-resistant layer and a sample including no intermediate layer were prepared. The composition of the intermediate layer is TiAlWNbSiN, in particular, Al₄₉Ti₄₆W₂Nb₂Si₁N. A cutting test was then performed on the prepared samples under the following conditions.

### Cutting Test Conditions

Workpiece: SUS304
Cutting speed: 150 m/min
Feed: 0.2 mm/rev
Cut depth: 1 mm
Cutting state: Wet
Tool used: CNMG120408SG

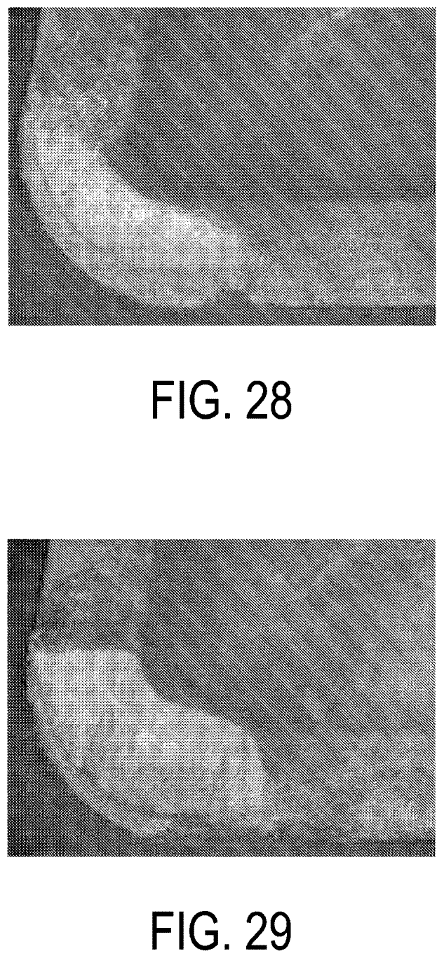

FIGS. 28 and 29 illustrate cutting edge states after cutting for 39 minutes under the above cutting conditions. FIG. 28 illustrates an image of a cutting edge state of the sample including the intermediate layer, taken from a direction perpendicular to a rake face after the cutting test. FIG. 29 illustrates an image of a cutting edge state of the sample including no intermediate layer, taken from the direction perpendicular to the rake face after the cutting test.

As is clear from the images illustrated in FIGS. 28 and 29, it can be seen that the crater wear occurring at the rake face is suitably suppressed by interposing the intermediate layer between the cohesion layer and the wear-resistant layer.

Proportions of Thicknesses of Intermediate Layer and Wear-Resistant Layer For a coated tool according to an example including: a cohesion layer made of TiAlNbWSi, in particular, Al₄₉Ti₄₆W₂Nb₂Si₁; an intermediate layer made of TiAlWNbSiN, in particular, Al₄₉Ti₄₆W₂Nb₂Si₁N; and a single wear-resistant layer made of TiAlCrWNbSiN, in particular, Al_{59.5}Ti₂₃Cr₁₅W₁Nb₁Si_{0.5}N, a plurality of samples different in proportions of the thicknesses of the intermediate layer and the wear-resistant layer were prepared. A coated tool including no intermediate layer and a coated tool including no wear-resistant layer were also prepared. Each of the prepared samples was subjected to a cutting test under the following conditions, and the cutting edge state after the cutting test was observed. The cutting time is 14.8 minutes.

### Cutting Test Conditions

Workpiece: Inconel (registered trademark) 718
Cutting speed (Vc): 30 m/min
Feed (f): 0.10 mm/rev
Cut depth (ap): 0.5 mm
Cutting state: Wet
Tool used: CNMG120408SG

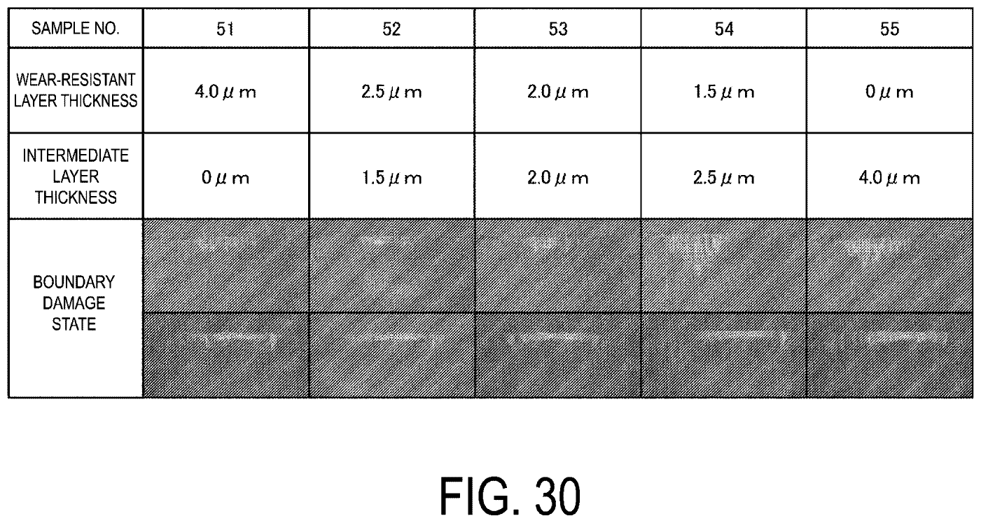

FIG. 30 is a table summarizing thicknesses of intermediate layers and wear-resistant layers of five samples different in thickness proportions of the intermediate layer and the wear-resistant layer and illustrates images illustrating their cutting edge states after the cutting test.

As illustrated in FIG. 30, Sample No. 51 is a sample including no intermediate layer. Specifically, Sample No. 51 has a wear-resistant layer thickness of 4 μm and an intermediate layer thickness of 0 μm. Sample No. 52 has a wear-resistant layer thickness of 2.5 μm and an intermediate layer thickness of 1.5 μm. The wear-resistant layer thickness and the intermediate layer thickness of Sample No. 53 are both 2 μm. Sample No. 54 has a wear-resistant layer thickness of 1.5 μm and an intermediate layer thickness of 2.5 μm. Sample No. 55 is a sample including no wear-resistant layer. Specifically, Sample No. 55 has a wear-resistant layer thickness of 0 μm and an intermediate layer thickness of 4 μm.

As illustrated in FIG. 30, it can be seen that Samples Nos. 54 and 55 in which the intermediate layer is thicker than the wear-resistant layer have greater boundary damage than those of Sample Nos. 51 to 53 in which the intermediate layer is thinner than the wear-resistant layer. From this result, the thickness of the intermediate layer is preferably equal to or less than the thickness of the wear-resistant layer.

Note that the shape of the coated tool 1 illustrated in FIG. 1 is merely an example and does not limit the shape of the coated tool according to the present disclosure. The coated tool according to the present disclosure may include a body having, for example, a rotation axis and a rod-like shape extending from a first end toward a second end, a cutting edge located at the first end of the body, and a groove extending in a spiral shape from the cutting edge toward the second end of the body.

Further effects and variations can be readily derived by those skilled in the art. Thus, a wide variety of aspects of the present invention are not limited to the specific details and representative embodiment represented and described above. Accordingly, various changes are possible without departing from the spirit or scope of the general inventive concepts defined by the appended claims and their equivalents.

1. A coated tool comprising:
a base body; and
a coating layer located on a surface of the base body, wherein
the coating layer contains at least one element selected from Group 4a, 5a and 6a elements under the periodic table, Al, Si, B, Y, and Mn, and at least one element selected from C and N, and
a first difference between a maximum value and a minimum value of a reflectance of the coating layer in a wavelength range of 400 nm or more and 1500 nm or less is 15% or less of the maximum value.

2. The coated tool according to claim 1, wherein
the reflectance of the coating layer in the wavelength range of 400 nm or more and 1500 nm or less is greater after use of the coated tool than before use.

3. The coated tool according to claim 1, wherein
the coating layer comprises a cohesion layer in contact with the base body and a wear-resistant layer, and
the wear-resistant layer is a single layer.

4. The coated tool according to claim 3, wherein
the wear-resistant layer has a Vickers hardness of 28 GPa or more.

5. The coated tool according to claim 3, wherein
the cohesion layer has a thickness of 2 nm or more and 8 nm or less.

6. The coated tool according to claim 1, wherein
the coating layer comprises the cohesion layer in contact with the base body, an intermediate layer in contact with the cohesion layer, and a wear-resistant layer in contact with the intermediate layer,
the intermediate layer contains: TiₑAl_{f}M_{g}, wherein M is at least one metal selected from Group 4a, 5a and 6a elements (excluding Cr) in the periodic table and Si, 0≤e≤55, 40≤f≤80, provided that e+f+g=100, in atomic ratio; and at least one nonmetal selected from carbon, nitrogen and oxygen.

7. The coated tool according to claim 1, wherein
the coating layer has a thickness of 2.5 μm or more and 10 μm or less.

8. The coated tool according to claim 1, wherein
the coating layer has a crystallite diameter of 200 Å or less.

9. A cutting tool comprising:
a rod-like holder comprising a pocket at an end portion thereof; and
the coated tool according to claim 1 located in the pocket.

10. The coated tool according to claim 1, wherein
the first difference is 10% or less of the first maximum value.

11. The coated tool according to claim 10, wherein
the first difference is 8% or less of the first maximum value.

12. The coated tool according to claim 1, wherein
a difference between a maximum value and a minimum value of a reflectance of the coating layer in a wavelength range of 400 nm or more and 800 nm or less is a second difference,
a difference between a maximum value and a minimum value of a reflectance of the coating layer in a wavelength range of 800 nm or more and 1500 nm or less is a third difference, and
the second difference is smaller than the third difference.

13. The coated tool according to claim 6, wherein
the wear-resistant layer contains: TiaAlbCrcMd, wherein M is at least one metal selected from Group 4a, 5a and 6a elements (excluding Cr) in the periodic table and Si, 15≤a≤40, 55≤b≤75, 10≤c≤20, 0≤d≤15, provided that a+b+c+d=100, in atomic ratio; and at least one nonmetal selected from carbon, nitrogen and oxygen.

14. The coated tool according to claim 6, wherein
a thickness of the intermediate layer is less than a thickness of the wear-resistant layer.
